(19) United States
(12) Patent Application Publication
(10) Pub. No.: US 2005/0270828 A1
(43) Pub. Date: Dec. 8, 2005

(54) Magnetic memory device and manufacturing method thereof

(75) Inventor: Makoto Motoyoshi, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Sony Corporation, Tokyo (JP)

(21) Appl. No.: 11/134,335

(22) Filed: May 23, 2005

(30) Foreign Application Priority Data
May 24, 2004 (JP) P2004-153745

(51) Int. Cl. G11C 11/00

(52) U.S. Cl. 365/158

(57) ABSTRACT

A magnetic memory device is proposed in which: a tunnel magnetic resistance effect element is configured by stacking a fixed magnetic layer whose direction of magnetization is fixed, a tunnel barrier layer, and a free magnetic layer whose direction of magnetization is variable in this order; and a second wiring is arranged opposite to the tunnel magnetic resistance effect element via an insulating layer on the side opposite a first wiring electrically connected to the tunnel magnetic resistance effect element, wherein a third wiring for reading electrically connected to the tunnel magnetic resistance effect element on the same side as the second wiring with respect to the tunnel magnetic resistance effect element is disposed within a connecting hole which is formed in an electrically isolated state with the second wiring while penetrating at least part of an area of the second wiring.

### CROSS REFERENCES TO RELATED APPLICATIONS

The present invention contains subject matter related to Japanese Patent Application JP 2004-153745 filed in the Japanese Patent Office on May 24, 2004, the entire contents of which being incorporated herein by reference.

### BACKGROUND OF THE INVENTION

1. Field of the Invention

The present invention relates to a magnetic memory device having a memory section composed of a magnetic memory element that is made by stacking a fixed magnetic layer whose magnetization direction is fixed, a tunnel barrier layer, and a free magnetic layer whose magnetization direction is variable. More particularly, the present invention relates to a magnetic memory device that is configured as a magnetic random access memory (MRAM), being called as a non-volatile memory, and a method of manufacturing the same.

2. Description of Related Art

As telecommunication equipments, in particular, personal small equipment such as portable terminals are spread rapidly, higher performances of higher integration, higher speed, and lower power consumption are increasingly demanded in elements such as memory and logic constituting the equipment of this kind.

It is estimated that especially non-volatile memories are essential in the era of Ubiquitous. In the event of power source exhaustion and trouble, and in the event of a disconnection between a server and a network due to some obstruction, the non-volatile memories are capable of protecting important information, including personal information. Although the recent portable equipment is designed to minimize power consumption by setting the unnecessary circuit block into its standby state, if a non-volatile memory available as high-speed work memory and large-capacity memory is achievable, it is possible to eliminate a waste of power consumption and memory. Further, the attainment of high-speed large-capacity non-volatile memory enables “instant-on” function that allows for quick start after turning on the power.

Examples of non-volatile memories are flash memories using semiconductors and ferroelectric random access memories (FRAMs) using ferroelectrics.

However, the flash memories have the drawback that the writing time of information is in the order of μ second, and therefore writing speed is low. While in the FRAMs it has been pointed out that writable number is 10¹² to 10¹⁴, and endurance is poor for completely replacing with static random access memory (SRAM) or dynamic random access memories (DRAMs), and the microfabrication of a ferroelectric capacitor is difficult.

A magnetic memory, being called as a magnetic random access memory (MRAM), is a good candidate for non-volatile memory that is free of the above-noted drawbacks, and has high speed, large capacity (high integration), and low power consumption.

Early MRAMs are based on a spin valve using anisotropic magnetoresistive (AMR) effect that is reported in J. M. Daughton, Thin Solid Films, vol. 216, pp. 162-168, 1992, or giant magnetoresistance (GMR) effect that is reported in D. D. Tang et al., IEDM Technical Digest, pp. 995-997, 1997. These memories, however, have the drawbacks that the memory cell resistance of load is as low as 10 to 100 Ω, and therefore power consumption per bit at the time of reading is large, and it is difficult to attain large memory capacity.

With regard to tunnel magnetoresistance (TMR) effect, originally there was only the material that is 1 to 2% in the rate of change of resistance at room temperature, as is reported in R. Meservey et al., Physics Reports, vol. 238, pp. 214-217, 1994. However, the material that is nearly 20% in the rate of change of resistance is now becoming available, as is reported in T. Miyazaki et al., J. Magnetisum & amp; Magnetic Material, vol. 139, (L231), 1995. By virtue of improvement in the TMR material characteristic in the recent years, MRAM using the TMR effect is becoming a good candidate.

A TMR element has the structure in which a tunnel barrier layer is interposed between two magnetic layers of a free magnetic layer (storage layer) and a fixed magnetic layer. The TMR element is a storage element that stores whether the magnetization directions of the two magnetic layers are “parallel” or “antiparallel,” as information of “0” or “1”, and reads the information by using the fact that the strength of the current flowing through the tunnel barrier layer varies according to the difference in the relative magnetization direction.

A TMR type MRAM has TMR elements arranged in the shape of a matrix, and has bit lines and word lines for access in the row direction and the column direction in order to store information in the desired TMR element. Thereby, information can be selectively written only into the TMR element positioned at a cross over region by the use of steroid characteristic to be described later.

The TMR type MRAM is a semiconductor magnetic memory that can read information by using magnetic resistance effect based on spin dependent conduction phenomenon inherent in nanomagnetic material, and is a non-volatile memory that can hold storage without supplying power from the exterior. In addition, its simple structure facilitates high integration. Since recording is accomplished with the reversal of magnetic moment, reloadable number is large and therefore it is expected that access time is also extremely high speed. Being operable at 100 MHz is already presented in R. Scheuerlein et al., ISSCC Digest of Technical Papers, pp. 128-129, February, 2000.

Now, the TMR type MRAM will be discussed in more detail.

FIG. 11A is a perspective view of a TMR element 10A that becomes a storage element of a memory cell of a MRAM. The TMR element 10A is disposed on a support substrate 7, and comprises a free magnetic layer (storage layer) 2, the magnetization direction of which is reversed relatively easily, and a fixed magnetic layer 4, the magnetization direction of which is fixed. For the free magnetic layer (storage layer) 2 and the fixed magnetic layer 4, a ferromagnetic is used which comprises mainly, for example, nickel, iron, cobalt, or these alloys. Alternatively, the fixed magnetic layer 4 may be a multilayered film having synthetic antiferromagnet (SAF) (a stacked film in which metal is interposed between ferromagnetics). The SAF is reported in S. S. Parkin et al., Physical Review Letters, 7, May, pp. 2304-2307 (1990).

The fixed magnetic layer 4 is formed in contact with an antiferromagnet layer 5, and the exchange interaction exerted between the two layers imparts strong one-directional magnetic anisotropy to the fixed magnetic layer 4. The material of the antiferromagnetic layer 5 is, for example, a manganese alloy of iron, nickel, platinum, iridium or rhodium, or an oxide of cobalt or nickel.

The free magnetic layer (storage layer) 2 has an easy axis of magnetization parallel to the magnetization direction of the fixed magnetic layer 4 (a directional axis on which a ferromagnetic is easily magnetized), and is susceptible to magnetization in either direction of parallel or antiparallel to the magnetization direction of the fixed magnetic layer 4, so that it is relatively easy to reverse the magnetization direction between these two states. Therefore, when the free magnetic layer (storage layer) 2 is used as information storage medium, the two states of the free magnetic layer (storage layer) 2 that is magnetized in “parallel” and “antiparallel” to the magnetization direction of the fixed magnetic layer 4 are associated with “0” and “1” of information.

Disposed between the free magnetic layer (storage layer) 2 and the fixed magnetic layer 4 is a tunnel barrier layer 3, which is made by an insulator composed of an oxide or a nitride of aluminum, magnesium, silicon, etc. The tunnel barrier layer 3 serves to cut a magnetic coupling between the free magnetic layer (storage layer) 2 and the fixed magnetic layer 4, and pass tunnel current in accordance with the magnetization direction of the free magnetic layer (storage layer) 2. Sputtering method is mainly used to form a magnetic layer and a conductor layer of the TMR element 10A. The tunnel barrier layer 3 is obtainable by oxidizing or nitriding a metal film formed by sputtering.

A top coat layer 1 has the functions of preventing mutual diffusion between the TMR element 10A and the wiring connected to the TMR element 10A, reducing contact resistance, and preventing oxidation of the free magnetic layer (storage layer) 2. The material of the top coat layer 1 is normally copper, tantalum, titanium nitride, or titanium. An lead electrode layer 6 is used to make connection with a read transistor etc. to be connected in series to the TMR element 10A. The lead electrode layer 6 may also serve as the antiferromagnetic material layer 5.

FIG. 11B is a perspective view of a TMR element 10B that is used as a storage element of a memory cell of a cross point type MRAM to be described later. In the TMR element 10B, instead of the lead electrode layer 6 and a substrate 7 of the TMR element 10A, a pn junction diode layer 201 is disposed, which is directly joined to word lines 12 to be described later. It is, however, possible to omit the pn junction diode layer 201.

The memory cells of a MRAM can be classified in two principal types. One is a cross point type MRAM cell in which a TMR element is used solely. The other is a MRAM cell of the type in which a TMR element is used together with a selective element such as a read transistor, more specifically, a MRAM cell having a 1T1J structure in which one selective element is disposed for one TMR element, or a 2T2J structure in which the 1T1J structure is disposed complementarily, that is, two selective elements are disposed for two TMR elements.

FIG. 12A is an enlarged perspective view illustrating part of a memory cell of a cross point type MRAM. Here, nine memory cells are shown as an example. In this MRAM, bit lines 11 and word lines 12 cross each other, and the TMR element 10B are arranged in the shape of a matrix between layers, at which these lines 11 and 12 cross each other.

FIG. 12B is a plan view showing a cell layout of a cross point type MRAM. The cross point type MRAM achieves 4F² in the minimum area of a memory cell, wherein F is the minimum dimension of a wiring on a design rule. In the absence of a switching element per element, access speed may be slow, but a large capacity memory is available.

FIGS. 13 and 14 show equivalent circuit diagrams of a 1T1J type MRAM. Specifically, FIG. 13 shows an overall construction. FIG. 14 is a partially enlarged view thereof, illustrating six memory cells as an example. The TMR elements 10A are arranged in the shape of a matrix between layers at which read bit lines 13 and write word lines 14 cross each other, and electric field effect transistors 18 for selecting the corresponding TMR element 10A when reading information are disposed, which are connected in series to the TMR element 10A.

Furthermore, there are disposed read bit lines 15, read word lines 16 for controlling ON/OFF of the electric field effect transistors 18, and sense lines 17 for outputting the read information. In a peripheral circuit section, write bit line current driving circuits 19 are connected to the write bit lines 13, write word line current driving circuits 20 are connected to the write word lines 14, read bit line driving circuits 21 are connected to the read bit lines 15, read word line driving circuits 22 are connected to the read word lines 16, and sense amplifiers 23 for detecting the read information are connected to the sense lines 17.

FIG. 15 is a perspective view showing one example of the memory cells of a conventional 1T1J type MRAM, and FIG. 16 is a schematic sectional view thereof. For convenience, FIG. 16 illustrates an interlayer insulating film 50, omitting the boundaries therebetween and hatching.

Above the memory cell, the write bit line 13 and the read bit line 15 are disposed with an interlayer insulating film 56 interposed therebetween, and the TMR element 10A adjoins and underlies the read bit line 15. In addition, the write word line 14 is disposed under the lead electrode layer 6 of the TMR element 10A, with an insulating layer interposed therebetween.

On the other hand, under the memory cell, for example, an electric field effect transistor 18 of n-type metal oxide semiconductor (MOS), which consists of a drain electrode 33, a drain region 34, a gate electrode 16, a gate insulating film 35, a source region 36, and a source electrode 37, is disposed at a p-type well region 31 formed within a p-type silicon semiconductor substrate 30. The gate electrode 16 of the transistor 18 is formed in the shape of a strip so as to make connection between cells, and it also serves as the read word line 16. The drain electrode 33 is connected to the lead electrode layer 6 of the TMR element 10A via a read wiring 210 consisting of an extraction wiring 202, read connecting plugs 211, 213, 215, and read landing pads 212, 214, 216. The source electrode 37 is connected to the sense line 17.

In the memory cell so constructed, the writing of information to the TMR element 10A is performed by passing current to the write bit line 13 and the write word line 14, and determining, depending on the synthetic magnetic field of magnetic fields generated from these lines, whether the direction of magnetization of the free magnetic layer (storage layer) 2 is “parallel” or “antiparallel” with respect to the direction of magnetization of the fixed magnetic layer 4.

In the magnetic field within the free magnetic layer (storage layer) 2 of the TMR element 10A, normally, a magnetic field in the direction of easy axis of magnetization HEA is applied by the write current passing through the write bit line 13, a magnetic field in the direction of hard axis of magnetization HHA is applied by the write current passing through the write word line 14, thereby exerting a synthetic magnetic field derived as a composition of vectors of these magnetic fields HE_{A} and HHA.

In the MRAM, writing is generally performed by applying the magnetic field HE_{A} (<one-directional reversing magnetic field Hk) and HHA (<Hk), the each intensity of which is insufficient to cause the reversal of magnetization, such that the reversal of a magnetic spin is generated only at the memory cell located at a cross-over point of the write bit line 13 and the write word line 14, through which the current is passing by the use of asteroid magnetization reversal characteristic, and on which the two magnetic fields HE_{A} and HHA are both exerted. This principle will be described below in detail (see the description of U.S. Pat. No. 6,081,445).

FIG. 17 is a graph of an asteroid curve showing the magnetic field response characteristic of the free magnetic layer (storage layer) 2 of the TMR element during information writing operation. Under a minimum energy condition, the asteroid curve is given by the following equation:
HE_{A}^{2/3}+HHA^{2/3}=HS^{2/3}
which expresses the writing condition of the TMR element, that is, a threshold value at which the direction of magnetization of the free magnetic layer (storage layer) 2 can be reversed by the magnetic field applied. Here, the magnitude of a switching magnetic field Hk depends not only the material of the free magnetic layer (storage layer) 2 but also the shape thereof.

As shown in FIG. 17, letting the magnetic field HE_{A} applied in the direction of easy axis of magnetization be Hx (<Hk) and the magnetic field HHA applied in the direction of hard axis of magnetization be Hy (<Hk), the direction of magnetization of the free magnetic layer (storage layer) 2 can be reversed when the synthetic magnetic field H, a vector sum of Hx and Hy, is exerted on the free magnetic layer (storage layer) 2, and this synthetic magnetic field H is larger than a threshold value HC corresponding to a point C on the asteroid curve, and has such a magnitude that reaches an outer region 151 or 152 of the asteroid curve. On the other hand, the synthetic magnetic field H, the vector sum of which stays at an inner region 150 of the asteroid curve, cannot reverse the direction of magnetization of the free magnetic layer (storage layer) 2.

The above-mentioned magnetization direction reversing characteristic indicates the principle that, when the magnetic field in the direction of easy axis of magnetization HE_{A} and the magnetic field in the direction of hard axis of magnetization HHA coexist, the magnitude of magnetic field necessary for reversing the direction of magnetization can be reduced than the case where each magnetic field is exerted solely, and the use of two write lines of the write bit line 13 and the write word line 14 permits to selectively write information only at the TMR element 10A of the memory cell located at the cross-over point of the two lines.

Specifically, by means of the write current passing though a write bit line 13, Hx, which is the magnetic field in the direction of easy axis of magnetization HE_{A}, is applied to all of the TMR elements 10A disposed under the write bit line 13. Likewise, by means of the write current passing though a write word line 14, Hy, which is the magnetic field in the direction of hard axis of magnetization HHA, is applied to all of the TMR elements 10A disposed above the write word line 14. However, when a single magnetic field is exerted in the direction of easy axis of magnetization or the direction of hard axis of magnetization, the threshold value of a magnetic field necessary for reversal of magnetization is a value on the easy axis of magnetization (X axis) or the hard axis of magnetization (Y axis) of the above-mentioned asteroid curve, that is, the one-directional reversing magnetic field Hk. Therefore, even when either Hx or Hy, each smaller than Hk, is exerted, either one alone cannot reverse the direction of magnetization of the free magnetic layer (storage layer) 2. However, at a memory cell which is located at the cross-over point between the write bit line 13 and the write word line 14, and on which Hx and Hy are both exerted, its synthetic magnetic field H exceeds a threshold value HC on the asteroid curve and reaches an outer region 151(A) of the asteroid curve. This enables to reverse the direction of magnetization of the free magnetic layer (storage layer) 2.

If Hx or Hy is larger than the one-directional reversing magnetic field Hk, information happens to be written into all of memory cells, to which this Hx or Hy is applied. Accordingly, Hx and Hy should be less than Hk, and hence a region 152 is unsuitable. Thus, a region suitable for a synthetic magnetic field, which is applied to the free magnetic layer (storage layer) 2 in order to write information, is the region 151(A) expressed in gray in FIG. 17.

FIG. 18 is a schematic sectional view for explaining information read operation in the TMR element 10A. Here, the layer configuration of the TMR element 10A is illustrated schematically, omitting a top coat layer 1, an antiferromagnet layer 5, and an lead electrode layer 6.

Reading of the information stored in the TMR element 10A is performed by using TMR effect that is one of magnetoresistance effects. Here, the TMR effect means the phenomenon that the resistance with respect to the tunnel current passing through two magnetic layers, which are oppositely disposed with a tunnel barrier layer interposed therebetween, becomes small when the directions of magnetic spins of the two magnetic layers are “parallel,” and becomes large when they are “antiparallel.”

More specifically, as shown in FIG. 18, the tunnel current, passing through the write bit line 13 to the free magnetic layer (storage layer) 2, the tunnel barrier layer 3, and then the fixed magnetic layer 4, is supplied to extract the read current corresponding to the magnitude of the above-noted resistance, and the direction of the magnetic spin of the free magnetic layer (storage layer) 2 is detected by the magnitude of the read current.

In other words, as shown in the left drawing of FIG. 18, when the directions of magnetization of the free magnetic layer (storage layer) 2 and the fixed magnetic layer 4 are “parallel” and the magnetic spins line up, the resistance between these two layers is small and therefore a large read current passes through the tunnel barrier layer 3. On the other hand, as shown in the right drawing of FIG. 18, when the directions of magnetization of the free magnetic layer (storage layer) 2 and the fixed magnetic layer 4 are “antiparallel” and the magnetic spins are in the opposite direction, the resistance between these two layers is large and therefore the read current passing through the tunnel barrier layer 3 is small.

As shown in FIG. 16, the lead electrode layer 6 of the TMR element 10A is connected to the drain electrode 33 of the read transistor 18 by the extraction wiring 202 and the read wiring 210. The source electrode 37 of the read transistor 18 is connected to the sense line 17. Therefore, during the read operation of the MRAM, in the TMR elements 10A connected to the read bit line 15 to which a driving voltage is applied, only the read current of the TMR element 10A selected by applying a control signal to the gate electrode (read word line) 16 is outputted to the sense line 17 via the read electric field effect transistor 18. Thus, the electric field effect transistor 18 functions as a switching element for selectively read the information stored in the TMR element 10A.

The transistor 18 may be an n-type or a p-type electric field effect transistor. In addition, a variety of switching elements such as a diode, a bipolar transistor, and a metal semiconductor field effect transistor (MESFET) are usable.

As discussed above, the 1T1J type MRAM as shown in FIG. 16 is capable of performing write operation and read operation almost simultaneously, because the write bit line 13 and the word line 14, and the read bit line 15 and the word line 16, are disposed independently (see M. Durlam et. al., International Electron Devices Meeting Technical Digest, pp. 995-997 (2003)). In this case, the write bit line 13 and the word line 14, and the read bit line 15 and the word line 16, must be electrically isolated.

Alternatively, the write bit line 13 and the read bit line 15 can share the same wiring, like many of MRAMs whose experimental manufacture results have been reported in the past, such as U.S. Pat. No. 5,940,319 (pp. 2-4, FIGS. 1-13). Also in this case, the write word line 14 and the read word line 16 must be electrically isolated.

In either case, as shown in FIG. 16, the write word line 14 is as close to the lead electrode layer 6 as possible, and disposed directly thereunder so that the magnetic field generated by the current passing through the write word line 14 acts effectively on the TMR element 10A. The wiring extending between the lead electrode layer 6 and the read word line 16 is placed at a position offset from the underside of the TMR element 10A by disposing the extraction wiring 202, in order to avoid contact with the write word line 14. At this position, there are normally formed read wirings 210, such as read connecting plugs 211, 213, 215 and read landing pads 212, 214, 216, to provide a connection to the read transistor 18.

FIG. 19 is a plan view showing a cell layout of the conventional 1T1J type MRAM shown in FIG. 16. In the MRAM of this type, letting a minimum dimension of wiring on the design rule be F, the length of a memory cell in the direction along the bit line is given by adding a length F for arranging the read wiring 210 at an offset position, to a length 3F necessary for arranging the write word line 14 and the read word line 16, and it comes to 4F at a minimum. Accordingly, it is impossible to control the minimum area of the memory cell to not more than 8F². Hence, the 1T1J type MRAM is superior to the above-mentioned cross point type MRAM in access speed, but suffers from the problem that the degree of integration of the memory cell is less than one half.

As above described, the cross point type MRAM has the problem that access speed is slow, though it is possible to make a large-capacity memory that is small in the minimum area of a memory cell and large in the degree of integration. On the other hand, the 1T1J type MRAM and the like with a selective element have the problem that the minimum area of a memory cell is large and the degree of integration of a memory cell is less than one half, though they are excellent in access speed.

### SUMMARY OF THE INVENTION

Therefore, the present invention is to presents a magnetic memory device with a selective element, which is excellent in access speed, small in the minimum area of a memory cell, and suppresses a reduction in the degree of integration of the memory cell, as well as a method of manufacturing the same.

In a magnetic memory device of the invention, a magnetic memory element is composed of a tunnel magnetic resistance effect element made by stacking: a fixed magnetic layer whose direction of magnetization is fixed, a tunnel barrier layer, and a free magnetic layer whose direction of magnetization is variable in this order. On the side opposite a first wiring electrically connected to the tunnel magnetic resistance effect element, a second wiring is arranged opposite to the tunnel magnetic resistance effect element via an insulating layer. On the same side as the second wiring with respect to the tunnel magnetic resistance effect element, a third wiring for reading electrically connected to the tunnel magnetic resistance effect element is disposed within a connecting hole that penetrates at least part of an area of the second wiring and is formed in an electrically isolated state.

There is also provided a method of manufacturing this magnetic memory device. The method comprises the step of forming a second wiring; the step of forming a connecting hole penetrating at least part of an area of the second wiring; and the step of forming in the connecting hole a third wiring that is electrically isolated from the second wiring.

According to one embodiment of the invention, a magnetic memory device is proposed in which: a tunnel magnetic resistance effect element is configured by stacking a fixed magnetic layer whose direction of magnetization is fixed, a tunnel barrier layer, and a free magnetic layer whose direction of magnetization is variable in this order; and a second wiring is arranged opposite to the tunnel magnetic resistance effect element via an insulating layer on the side opposite a first wiring electrically connected to the tunnel magnetic resistance effect element, wherein a third wiring for reading electrically connected to the tunnel magnetic resistance effect element on the same side as the second wiring with respect to the tunnel magnetic resistance effect element is disposed within a connecting hole which is formed in an electrically isolated state with the second wiring while penetrating at least part of an area of the second wiring.

Preferably, an insulating layer is formed on the sidewall of the connecting hole, and the third wiring is buried at the inside of the insulating layer.

Preferably, the connecting hole penetrates the area of the second wiring.

Preferably, the second wiring is divided at least by the magnetic memory element, into both sides of the connecting hole.

Preferably, on the same side as the first wiring with respect to the tunnel magnetic resistance effect element, there is disposed a fourth wiring for writing that is electrically isolated from the tunnel magnetic resistance effect element.

In an alternative, preferably, the first wiring acts as the wiring for reading and the wiring for writing.

Preferably, the first wiring and the second wiring are arranged to cross each other, and the tunnel magnetic resistance effect element is arranged at the cross-point.

Preferably, the tunnel barrier layer is interposed between the fixed magnetic layer and the free magnetic layer, so that information is written by magnetizing the free magnetic layer in a predetermined direction with a magnetic field induced by passing current to the first or fourth wiring and the second wiring, and the written information is read through the third wiring by tunnel magnetic resistance effect via the tunnel barrier layer. These are a standard configuration of MRAMs.

### BRIEF DESCRIPTION OF THE DRAWINGS

FIG. 1 is a schematic sectional view of a memory cell of a 1T1J type MRAM according to a first preferred embodiment of the present invention;

FIG. 2A is a perspective view showing a calculation model for finding the relationship between the position at which a through hole is disposed, and the current value necessary for reversing magnetization; and FIGS. 2B-1 and 2B-2 are graphs showing the calculation results;

FIGS. 3A to 3K are schematic sectional views of important parts in the manufacturing steps of the MRAM;

FIGS. 4A to 4E are schematic sectional views of important parts in the manufacturing steps of a MRAM according to a second preferred embodiment of the invention;

FIGS. 5A to 5F are schematic sectional views showing important parts in the manufacturing steps of a MRAM according to a third preferred embodiment of the invention;

FIG. 6 is a schematic plan view of an important part of a MRAM according to a fourth preferred embodiment of the invention;

FIGS. 7A to 7F are schematic sectional views showing important parts in the manufacturing steps of the MRAM in the fourth preferred embodiment;

FIG. 8 is a schematic plan view showing an important part of a MRAM according to a fifth preferred embodiment of the invention;

FIG. 9 is a schematic sectional view of a memory cell of a 1T1J type MRAM according to other preferred embodiment of the present invention;

FIGS. 10A to 10C are plan views showing the shape of a connecting hole formed at a write word line according to preferred embodiments of the invention;

FIGS. 11A and 11B are schematic perspective views of a TMR element of a MRAM;

FIG. 12A is an enlarged perspective view showing part of a memory section of a cross point type MRAM; and FIG. 12B is a plan view showing a cell layout thereof;

FIGS. 13 and 14 are equivalent circuit diagrams of a 1T1J type MRAM;

FIG. 15 is a perspective view showing a conventional 1T1J type MRAM;

FIG. 16 is a schematic sectional view of a memory cell of the conventional 1T1J type MRAM;

FIG. 17 is a diagram showing magnetic field response characteristic at the time of writing in a MRAM;

FIG. 18 is a diagram showing the principle of the read operation of a MRAM; and

FIG. 19 is a plan view showing a cell layout of a conventional 1T1J type MRAM.

### DETAIL DESCRIPTION OF THE PREFERRED EMBODIMENTS

Preferred embodiments of the present invention will now be described in detail with reference to the accompanying drawings.

### First Preferred Embodiment

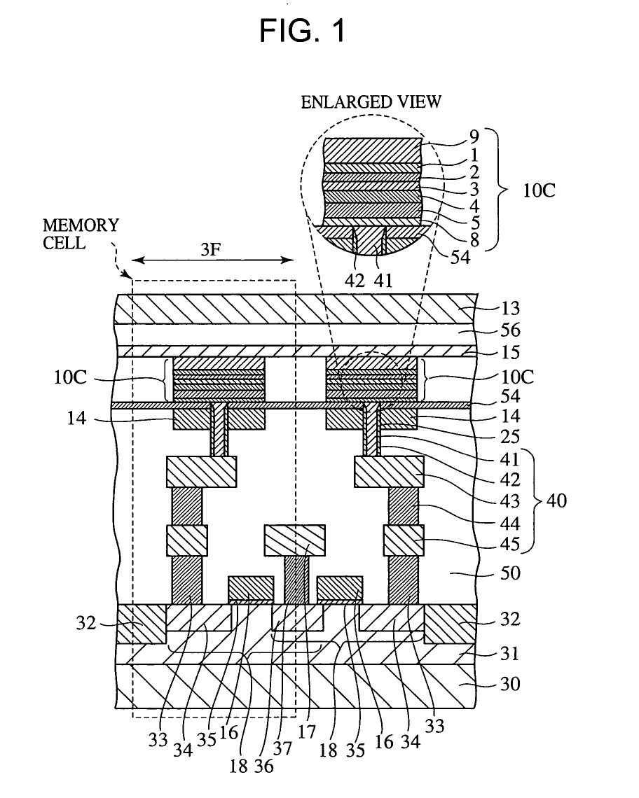

FIG. 1 is a schematic sectional view showing one of memory cells arranged at a memory section of a 1T1J type MRAM according to a first preferred embodiment. For convenience, FIG. 1 illustrates interlayer insulating films 50 and 56, omitting the boundaries therebetween and hatching.

Above the memory cell, a write bit line 13 and a read bit line 15 are disposed with an interlayer insulating film 56 interposed therebetween, and a TMR element 10C adjoins and underlies the read bit line 15. In addition, write word lines 14, which are the above-mentioned second wiring, are disposed in opposed positions under the TMR element 10C, interposing therebetween an insulating layer 54, which is the above-mentioned insulating layer.

On the other hand, under the memory cell, for example, an n-type MOS electric field effect transistor 18, which consists of a drain electrode 33, a drain region 34, a gate electrode 16, a gate insulating film 35, a source region 36, and a source electrode 37, is disposed at a p-type well region 31 formed within a p-type silicon semiconductor substrate 30. The gate electrode 16 of the transistor 18 is formed in the shape of a strip so as to make a connection between cells, and also serves as a read word line 16. The source electrode 37 is connected to a sense line 17.

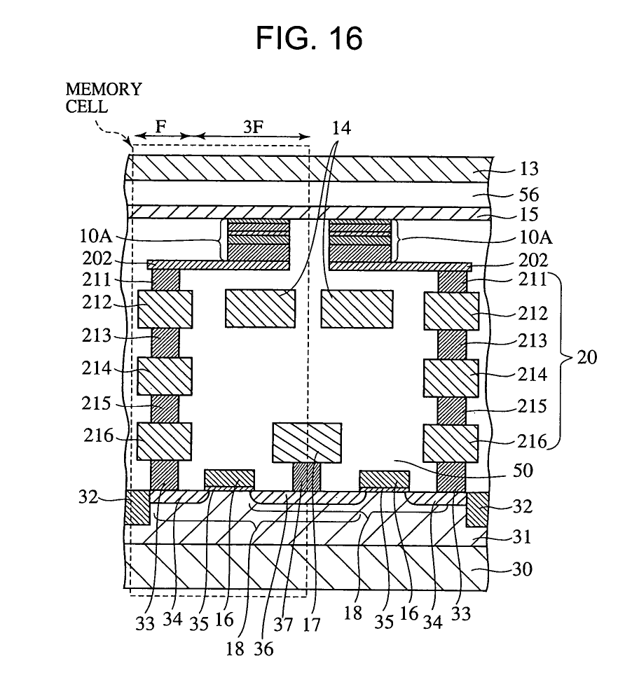

The foregoing points are the same as the conventional 1T1J type MRAM shown in FIG. 16. The different point is that, in the conventional MRAM, the read wiring 210 for connecting the TMR element 10A to the drain electrode 33 of the read transistor 18 is disposed at the position offset from immediately under the TMR element 10A, whereas in the MRAM of this embodiment a read wiring 40 for connecting the TMR element 10C to the drain electrode 33 of the read transistor 18 is disposed immediately under the TMR element 10C so as to penetrate the write word line 14.

Thereby, letting a minimum dimension of wiring on the design rule be F, there is the following difference in terms of the minimum dimension in the length direction of a bit line of a memory cell. That of the conventional MRAM is given by adding a length F for arranging the read wiring 210 at the offset position to a length 3F necessary for arranging the write word line 14 and the read word line 16, and it comes to 4F. In this preferred embodiment, it comes to 3F because the addition due to the offset of the read wiring 210 is eliminated, and the minimum area of a memory cell is 6F². This permits excellent access speed and approximately three-fourths of the degree of integration of the memory cell in the cross point type MRAM.

The MRAM in accordance with this preferred embodiment will next be described in more detail.

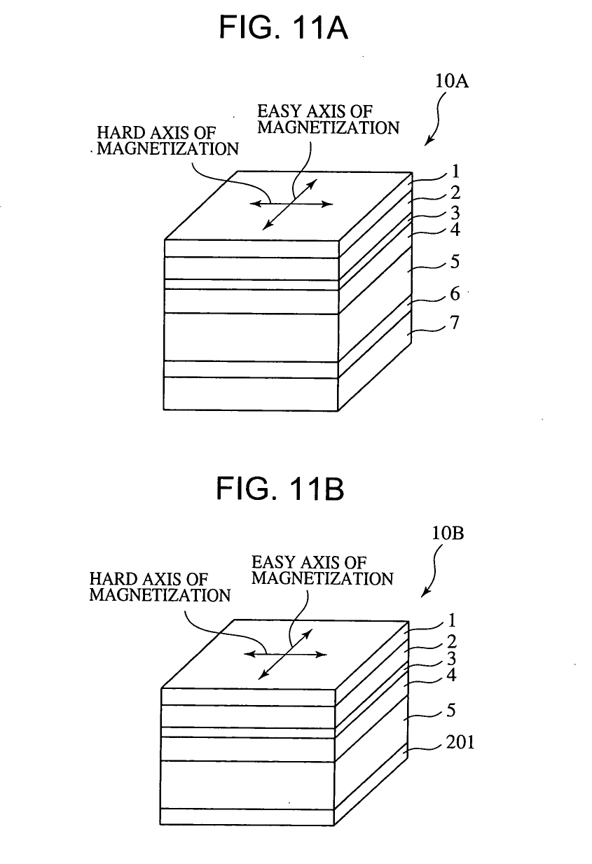

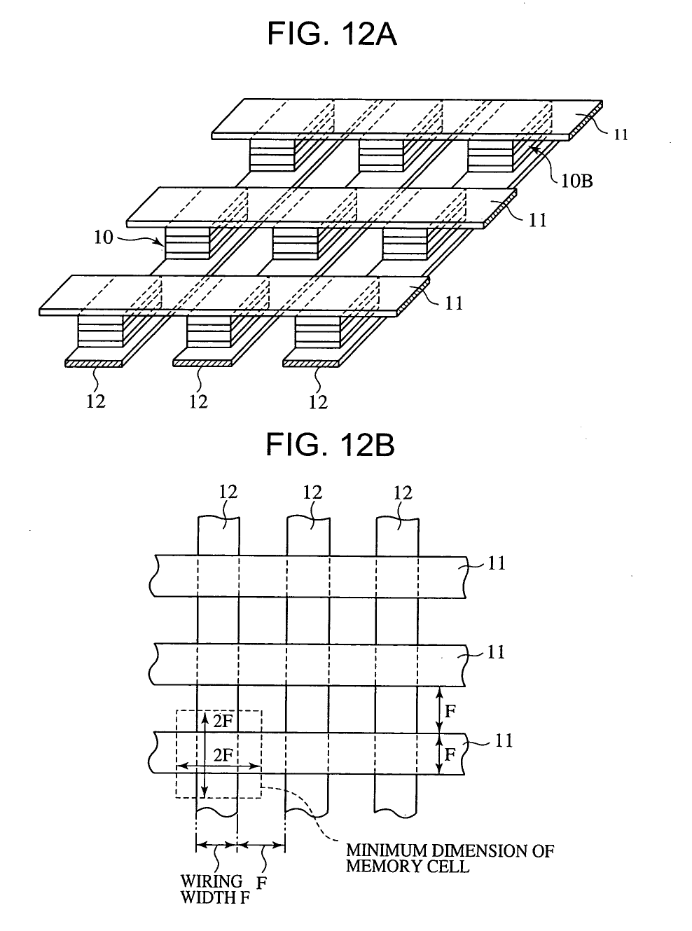

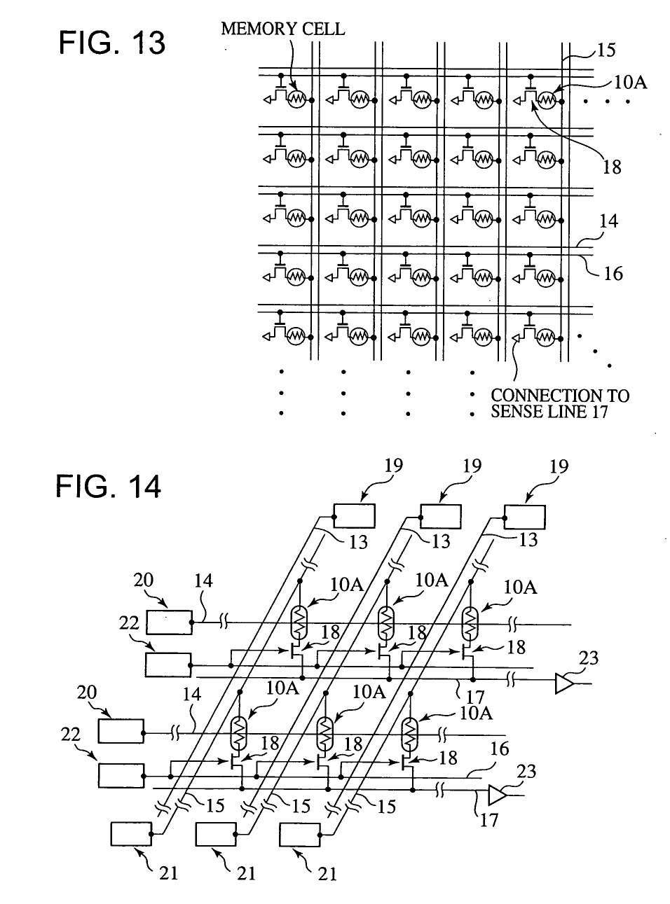

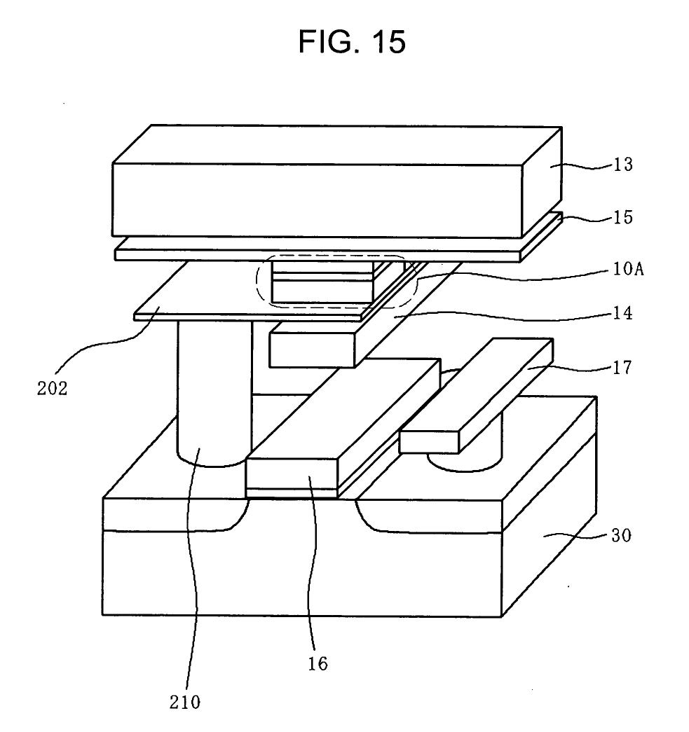

The basic structure of the TMR element 10C is the same as that of the conventional one shown in FIGS. 11A and 11B. The TMR element 10C contains a free magnetic layer (storage layer) 2, whose magnetization direction is reversed relatively easily, and a fixed magnetic layer 4, whose magnetization direction is fixed. For the free magnetic layer (storage layer) 2 and the fixed magnetic layer 4, a ferromagnetic is used which comprises mainly, for example, nickel, iron, cobalt, or these alloys. Alternatively, the fixed magnetic layer 4 may be a multilayered film having synthetic antiferromagnet (SAF) (a laminate film in which metal is interposed between ferromagnetics).

The fixed magnetic layer 4 is formed in contact with an antiferromagnet layer 5, and the fixed magnetic layer 4 has strong one-directional magnetic anisotropy by means of exchange interaction exerted between the two layers. The material of the antiferromagnetic layer 5 is, for example, a manganese alloy of iron, nickel, platinum, iridium or rhodium, or an oxide of cobalt or nickel.

The free magnetic layer (storage layer) 2 has an easy axis of magnetization parallel to the magnetization direction of the fixed magnetic layer 4 (a directional axis in which a ferromagnetic is easily magnetized), and is susceptible to magnetization in either direction of parallel or antiparallel to the magnetization direction of the fixed magnetic layer 4, so that the magnetization direction is relatively easily reversed between the two states. The free magnetic layer (storage layer) 2 is used as information storage medium by having the two states of the free magnetic layer (storage layer) 2, which is magnetized in “parallel” and “antiparallel” to the magnetization direction of the fixed magnetic layer 4, be associated with “0” and “1” of information.

Disposed between the free magnetic layer (storage layer) 2 and the fixed magnetic layer 4 is a tunnel barrier layer 3 made of an insulator that is composed of an oxide or a nitride of aluminum, magnesium, silicon, etc. The tunnel barrier layer 3 serves to cut a magnetic coupling between the free magnetic layer (storage layer) 2 and the fixed magnetic layer 4, and pass tunnel current in accordance with the magnetization direction of the free magnetic layer (storage layer) 2. A magnetic layer and a conductor layer that constitute the TMR element 10C are obtainable mainly by sputtering method or molecular beam epitaxy (MBE) method. The tunnel barrier layer 3 is obtainable by oxidizing or nitriding a metal film formed by sputtering method, alternatively, by forming an oxide layer by MBE method or sputtering method.

A top coat layer 1 has the functions of preventing mutual diffusion between the TMR element 10C and the wiring connected to the TMR element 10C, reducing contact resistance, and preventing oxidation of the free magnetic layer (storage layer) 2. The material of the top coat layer 1 is normally copper, tantalum, titanium nitride, or titanium.

In addition to the foregoing, the TMR element 10C has a bit line connecting layer 9 above the top coat layer 1. The bit line connecting layer 9 is a conductor layer for electrically connecting to the read bit line 15. The material of the bit line connecting layer 9 is normally tungsten or titanium nitride.

Instead of the lead electrode layer 6 in the conventional TMR element 10A, a barrier layer 8 for connecting to the read wiring 40 is disposed under the antiferromagnetic layer 5. The barrier layer 8 has the function of preventing mutual diffusion between the TMR element 10C and the wiring connected to the TMR element 10C, and reducing contact resistance. The material of the barrier layer 8 is normally copper, tantalum, titanium nitride, or titanium.

Write word lines 14 are disposed in opposed positions via an insulating layer 54 under the barrier layer 8. The insulating layer 54 is an aluminum oxide (alumina) layer having a thickness of 50 nm, for example. A connecting hole 25, which is the above-mentioned connecting hole, is formed so as to penetrate the insulating layer 54 and the write word line 14. A read connecting plug 41 is formed by burying, for example, tungsten within the connecting hole 25, and is electrically isolated from the write word line 14 by an insulation sidewall 42. The read connecting plug 41 is connected to the barrier layer 8 of the TMR element 10C. The read connecting plug 41 forms the read wiring 40 together with the read landing pads 43, 45 and the read connecting plug 44, and it is electrically connected to the drain electrode 33 of the read transistor 18 of the TMR element 10C, thereby functioning to introduce the read current of the TMR element 10C into the sense line 17.

In the memory cell so configured, the writing of information to the TMR element 10C is performed by passing current to the write bit line 13 and the write word line 14, and determining, depending on the synthetic magnetic field of the magnetic fields generated from these lines, whether the direction of magnetization of the free magnetic layer (storage layer) 2 is “parallel” or “antiparallel” with respect to the direction of magnetization of the fixed magnetic layer 4. This direction is then associated with “0” and “1” of information.

In the magnetic field at the free magnetic layer (storage layer) 2, a magnetic field in the direction of easy axis of magnetization HEA is applied by the write current passing through the write bit line 13, a magnetic field in the direction of hard axis of magnetization HHA is applied by the write current passing through the write word line 14, and the synthetic magnetic field by means of composition of vectors of these magnetic fields HEA and HHA is exerted.

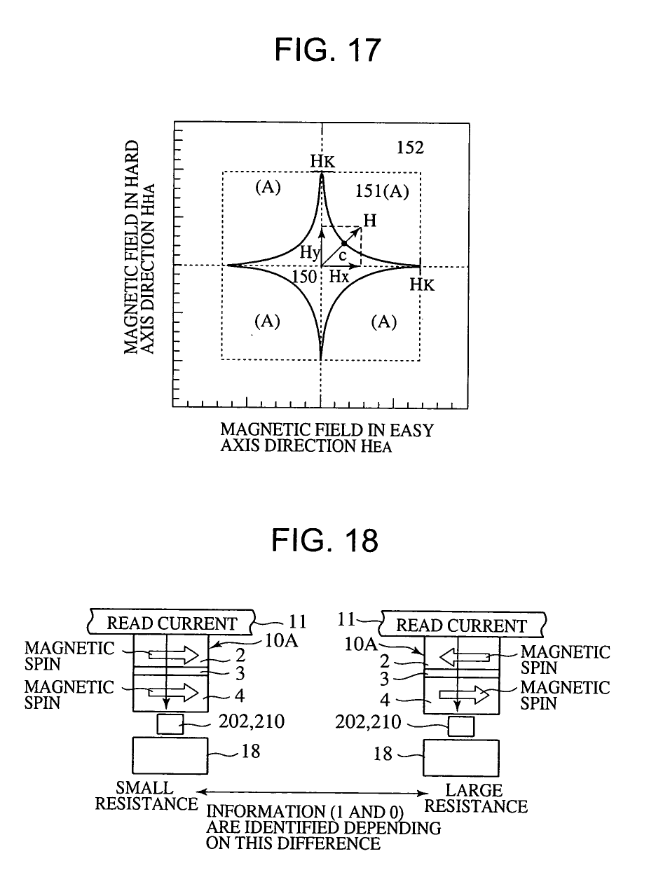

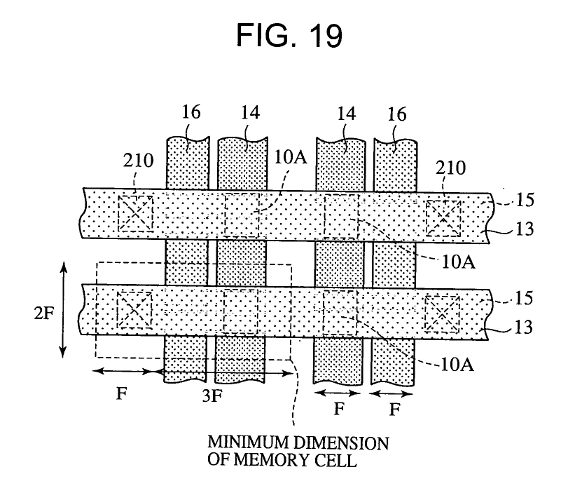

FIG. 17 is an asteroid curve showing the write conditions of the MRAM, and indicates the threshold value at which the reversal of magnetization direction of the free magnetic layer (storage layer) 2 is caused by the applied magnetic fields HEA and HHA. When the synthetic magnetic field representing the outside of this asteroid curve is generated, the reversal of magnetization is possible. With the synthetic magnetic field representing the inside of this asteroid curve, the magnetization direction of the free magnetic layer (storage layer) 2 cannot be reversed from one to the other. In the MRAM, writing is performed by applying magnetic fields HEA and HHA, only either one of which cannot cause the reversal of magnetization, such that the reversal of magnetic spin is generated only at a designated memory cell by making use of asteroid magnetization reversal characteristic.

Also in cells other than the cell at the cross-over point of the write bit line 13 and the write word line 14, through which current is allowed to flow, the magnetic field generated only by the write bit line 13 or the write word line 14 is applied. Therefore, when their respective magnitude is not less than a one-directional reversed magnetic field HK, the magnetization direction of the cells other than the cell at the cross-over point is also reversed. Hence, in the magnetic field generated only by the write bit line 13 or the write word line 14, for example, the magnitude of current, which is allowed to flow through the write bit line 13 and the write word line 14, is adjusted such that the synthetic magnetic field falls within a gray region 151(A) in FIG. 17, in order to avoid the reversal of magnetization direction of the free magnetic layer (storage layer) 2.

Reading of information is accomplished by using TMR effect, to which magnetic resistance effect is applied. Specifically, the current (tunnel current) from the read bit line 15 is allowed to flow between the free magnetic layer (storage layer) 2 and the fixed magnetic layer 4 with the tunnel barrier layer 2 interposed therebetween, and the output current in accordance with the magnitude of the above-mentioned resistance is fetched into the sense line 17 via the read electric field effect transistor 18.

With the structure in which the read connecting plug 41 penetrates the write word line 14, there is a fear that the magnetic field to be formed on the free magnetic layer 2 can change due to the influence of the read connecting plug 41 and the influence of a deviation of alignment between the read connecting plug 41 and the write word line 14. To consider this point, a through hole is formed in the write word line 14, and the relationship between the position at which this through hole is disposed and the current value necessary for reversal of magnetization is found by simulation with the use of “Micromag (trade name),” which is an analytical software.

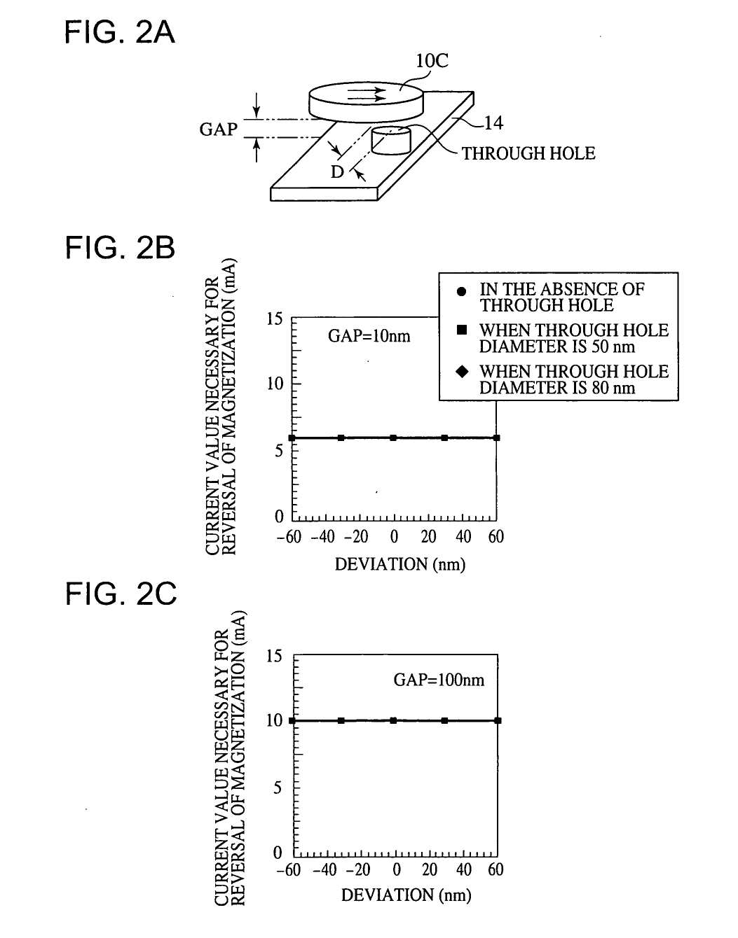

FIG. 2A is a perspective view showing a calculation model. FIGS. 2B-1 and 2B-2 are graphs showing the results of calculations. The TMR element 10C is shaped in an ellipse having a major axis of 0.26 μm and a minor axis of 0.13 μm. Letting a deviation between the center of the TMR element 10C and the center of the through hole be D, the relationship between the deviation D and the current value necessary for reversal of magnetization was found. Calculation was performed for two cases where the gap between the write word line 14 and the TMR element 10C is 10 nm and 100 nm. The results are presented in FIGS. 2B-1 and 2B-2. With regard to the two cases, calculation was further performed under the following conditions: in the absence of a through hole; when the through hole has a diameter of 50 nm; and when the through hole has a diameter of 80 nm. The results of these calculations are overlapped on the graphs and therefore indistinguishable.

Now that there is no significant difference among the three calculation results obtained in the absence of a through hole; when the through hole has a diameter of 50 nm; and when the through hole has a diameter of 80 nm, and that even if the deviation D is changed, the reverse current is constant irrespective of the deviation D, as shown in FIG. 2B-1 and 2B-2, it can be concluded that the read connecting plug 41 disposed on the write word line 14 exerts little influence on the intensity of the magnetic field formed on the TMR element 10C.

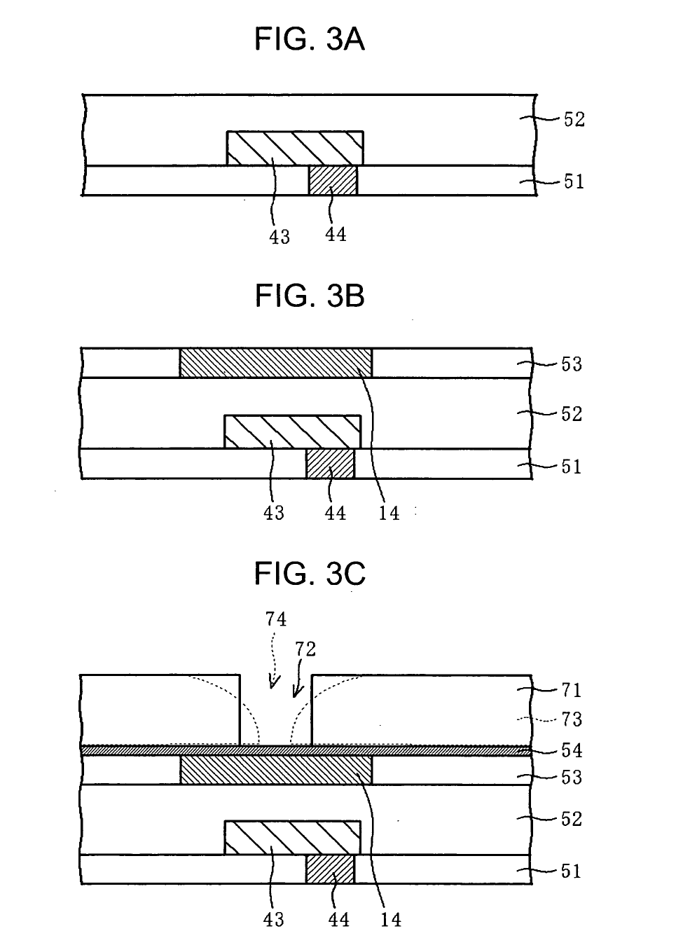

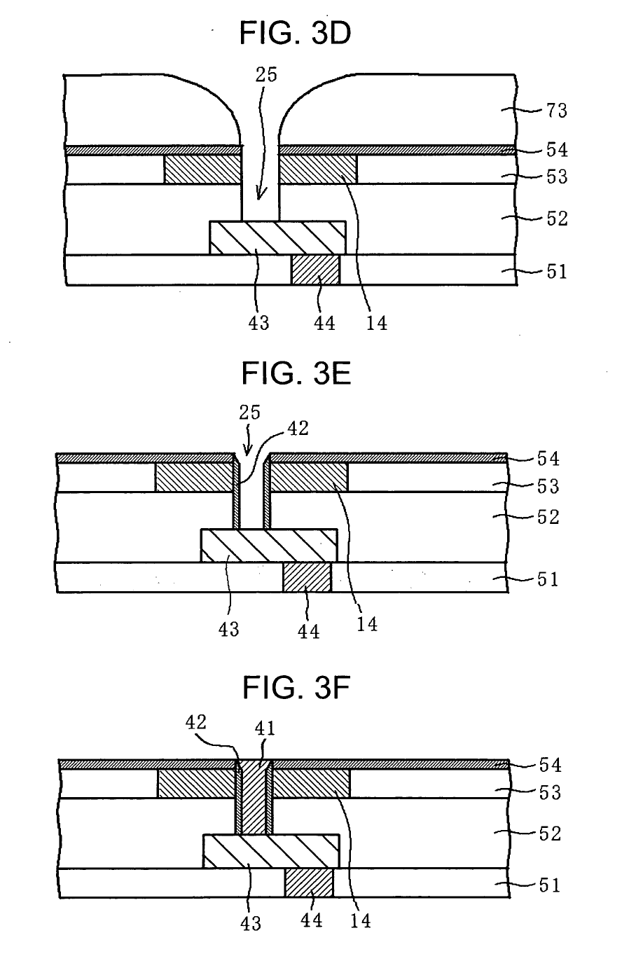

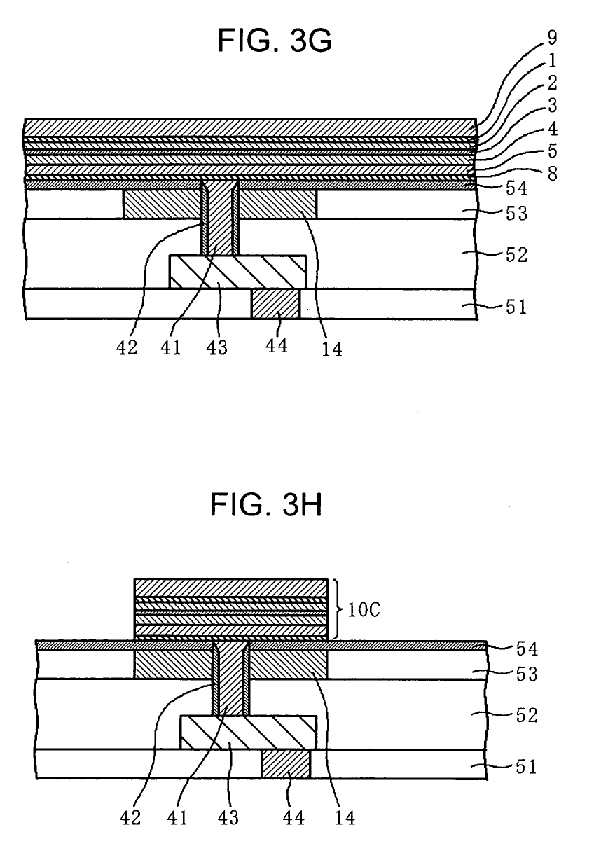

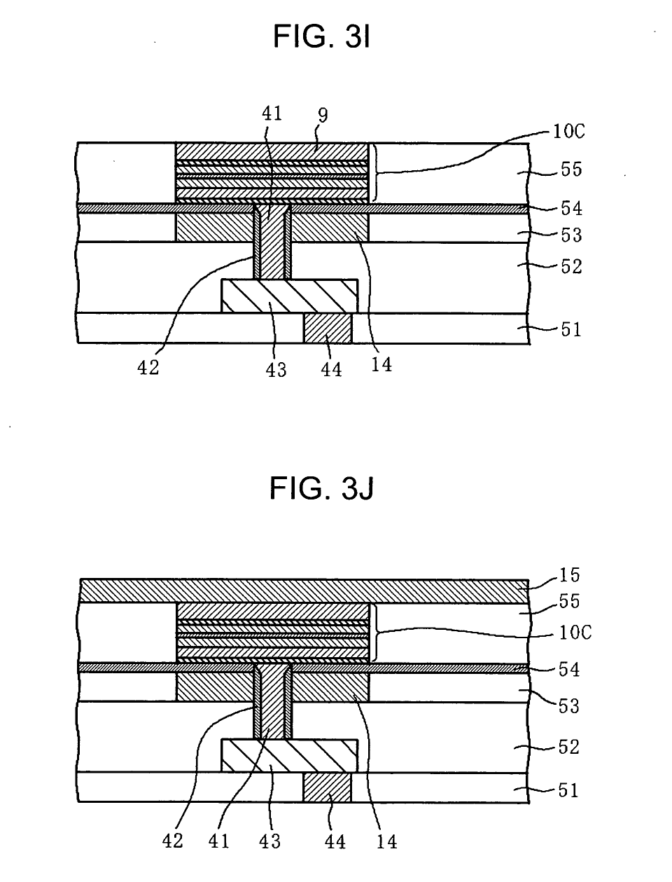

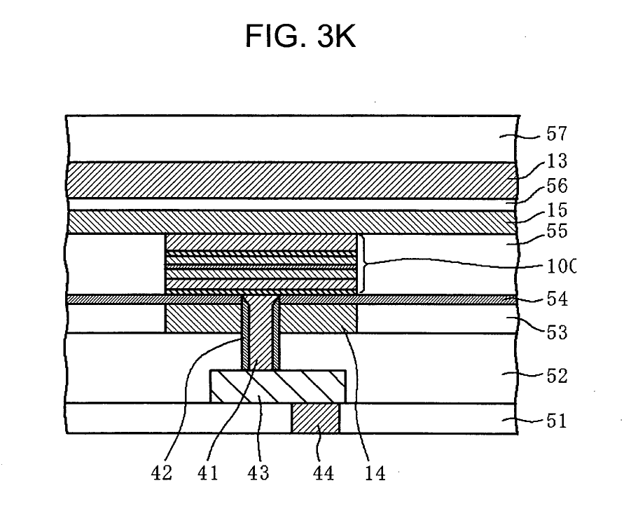

The flow of the manufacturing steps of the MRAM shown in FIG. 1 will next be described with reference to the schematic sectional views in FIGS. 3A to 3K. Since the process up to the step of forming an underlayer wiring are the same as the conventional one, these steps will be explained in brief.

First, for example, read MOS electric field effect transistors 18 and an oxide film 32, such as shallow trench isolation (STI), for separating the transistors 18, are formed in a p-type well region 31 of a silicon substrate 30 by a known semiconductor technique.

Subsequently, on an insulating film stacked thereon, an underlayer wiring is formed. For example, a copper wiring can be formed in the following steps. As an interlayer insulating film, an oxide silicon film is deposited by chemical vapor deposition (CVD) method. The interlayer insulating film is then patterned by means of photolithography technique and dry etching. Thereafter, as a barrier layer, a thin film of tantalum or tantalum nitride is formed on the entire surface of the interlayer insulating film by sputtering method, and a wiring groove and an opening portion are filled with copper by CVD method or plating method, and the surface is then planarized by chemical mechanical polishing (CMP) method. When forming an aluminum wiring, an aluminum thin film is formed by sputtering method or deposition method, and then patterned by photolithography technique and dry etching.

On the lower structure so formed, an upper structure such as the TMR element 10C is manufactured. For the sake of simplicity, FIGS. 3A to 3K illustrate only the structure lying above an interlayer insulating film 51 where a read connecting plug 44 composed of tungsten is formed, and illustrate only the cross section of important parts in the vicinity of the TMR element 10C. Here, suppose that a read landing pad 43 is already formed on the read connecting plug 44. For convenience, almost all hatchings of the interlaying insulating film are omitted in FIGS. 3A to 3K (the same is true for the followings).

Referring to FIG. 3A, a silicon oxide film is deposited in a thickness of 1000 nm by high density plasma CVD method. This is then planarized by CMP, and an interlayer insulating film 52 is formed such that the silicon oxide film having a thickness of 500 nm is left on the read landing pad 43.

Referring to FIG. 3B, titanium (20 nm), titanium nitride (20 nm), aluminum-copper alloy (300 nm), titanium (10 nm), and titanium nitride (100 nm) are deposited sequentially and then patterned by etching with a photoresist as mask, thereby forming a write word line 14. Subsequently, a silicon oxide film is deposited in a thickness of 500 nm by high density plasma CVD method, and then planarized by CMP, such that the surface of the write word line 14 is exposed, thereby forming an interlayer insulating film 53.

Referring to FIG. 3C, an insulating layer 54 composed of aluminum oxide (alumina) is deposited in a thickness of 50 nm on the entire surface, and a photoresist layer is formed thereon. This photoresist layer is then patterned to form a photoresist 71 having an opening portion 72. Further, the photoresist 71 is heat-treated at 200 to 300° C., and the photoresist 71 is allowed to reflow, and the diameter of the opening portion 72 is reduced, thereby forming a photoresist 73 having an opening portion 74. In FIG. 3C, the solid line represents the cross-sectional shape of the photoresist 71, and the dotted line represents the cross-sectional shape of the after-reflow photoresist 73. Alternatively, the method of reducing the opening portion of the photoresist may be, for example, a method employing a sidewall formation, which is reported in T. Toyoshima et al., International Electron Device Meeting Technical Digest, pp. 333-336 (1998).

Referring to FIG. 3D, by etching using, as mask, the photoresist 73 with the opening portion 74 whose diameter is diminished, the insulating layer 54, the write word line 14 and the interlayer insulating film (silicon oxide film) 52 are etched sequentially, thereby forming a connecting hole 25 that reaches the read landing pad 43. The photoresist is then removed by ashing.

Referring to FIG. 3E, the silicon oxide film is deposited in a thickness of 20 nm by plasma CVD method, and etch back is then performed to form in the connecting hole 25 an insulation sidewall 42 composed of the silicon oxide film.

Referring to FIG. 3F, the connecting hole 25 with the insulation sidewall 42 is filled with a tungsten layer by CVD method, and the surface is then planarized by CMP, thereby forming a read connecting plug 41.

Referring to FIG. 3G, a barrier layer 8, an antiferromagnet layer 5, a fixed magnetic layer 4, a tunnel barrier layer 3, a free magnetic layer 2, and a top coat layer 1 are deposited sequentially by physical vapor deposition (PVD) method. Here, titanium nitride, tantalum, or tantalum nitride can be used for the barrier layer 8. Alloys such as iron-manganese, nickel-manganese, platinum-manganese, and iridium-manganese can be used for the antiferromagnet layer 5. Nickel/iron and/or alloy of cobalt can be used for the fixed magnetic layer 4. The magnetization direction of the fixed magnetic layer 4 is pinned by switched connection with the antiferromagnet layer 5. Normally, aluminum oxide (alumina: Al₂O₃) is used for the tunnel barrier layer 3. Since this alumina film is as thin as 0.5 to 5 nm, it is formed by atomic layer deposition (ALD) method, or a method of depositing aluminum by sputtering, followed by plasma oxidation. Like the fixed magnetic layer 4, nickel/iron and/or an alloy of cobalt can be used for the free magnetic layer 2. The magnetization direction of this layer can be parallel or antiparallel with respect to the magnetization direction of the fixed magnetic layer 4, depending on the application of an external magnetic field. The top coat layer 1 is formed by the same material as that of the barrier layer 8. Subsequently, a bit line connecting layer 9 composed of tungsten or titanium nitride is deposited in a thickness of 50 nm by CVD method.

Referring to FIG. 3H, the multiplayer films 9, 1 to 5, and 8, which are formed in the step shown in FIG. 3G, are etched to form the TMR element 10C.

Referring to FIG. 31, an interlayer insulating film 55 composed of silicon oxide is deposited in a thickness of 100 nm by plasma CVD method. The surface is then planarized by CMP, such that the bit connecting layer 9 composed of tungsten or titanium nitride is exposed.

Referring to FIG. 3J, a read bit line 15 is formed by a standard wiring forming technique. The material of the read bit line 15 is aluminum alloy, copper, or titanium nitride.

Referring to FIG. 3K, after an interlayer insulating film 56 is deposited, a write bit line 13, the wiring of a peripheral circuit (not shown), and a bonding pad region (not shown) are formed by a standard wiring forming technique. Further, an insulating film 57 composed of a silicon nitride film is deposited on the entire surface by plasma CVD method, and a bonding pad portion (not shown) is opened, thereby completing the wafer process for manufacturing the MRAM.

Thus, with the MRAM structure and the manufacturing method thereof according to the first preferred embodiment, the conventional extraction wiring portion can be eliminated, and the length in the direction along a bit line can be reduced. It is therefore possible to realize, as the area of a memory cell, a cell size of not more than 8F², where F is the minimum dimension of wiring on a design rule. Furthermore, since the TMR element 10C requires only one-stage etching, the TMR element can be manufactured by etching with relatively low accuracy.

### Second Preferred Embodiment

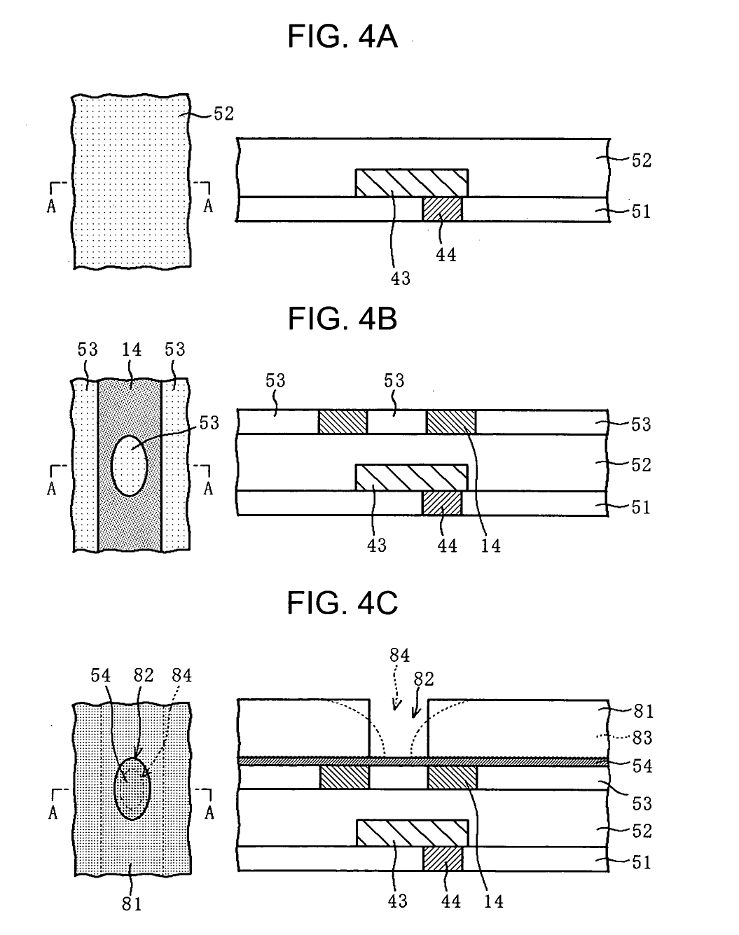

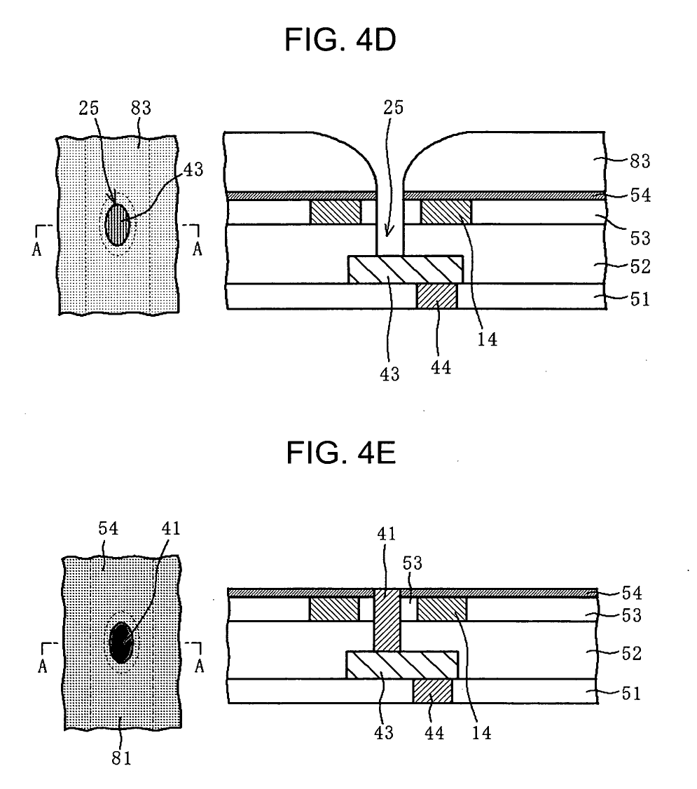

In FIGS. 4A to 4E, the left drawings are plan views showing the steps of manufacturing a MRAM, having substantially the same structure as the MRAM of the first preferred embodiment, by a method according to a second preferred embodiment, and the right drawings are sectional views taken along the line A-A in their respective plan views. These drawings represent from the same state as in FIG. 3A to the state corresponding to FIG. 3F. The descriptions of the succeeding steps are omitted because they are the same as in the first preferred embodiment.

Referring to FIG. 4A, a silicon oxide film is deposited in a thickness of 1000 nm by high density plasma CVD method. This is then planarized by CMP, and an interlayer insulating film 52 is formed such that the silicon oxide film having a thickness of 500 m is left on a read landing pad 43.

Referring to FIG. 4B, titanium (20 nm), titanium nitride (20 nm), aluminum-copper alloy (300 nm), titanium (10 nm), and titanium nitride (100 nm) are deposited sequentially and then patterned by etching with a photoresist as mask, thereby forming a write word line 14 in which, at the forming position of a read connecting plug 41, there is formed a through hole having an inner diameter slightly greater than the plug 41. Subsequently, a silicon oxide film is deposited in a thickness of 500 nm by high density plasma CVD method and then planarized by CMP, such that the surface of the write word line 14 is exposed, thereby forming an interlayer insulating film 53.

Referring to FIG. 4C, an insulating layer 54 composed of aluminum oxide (alumina) is deposited in a thickness of 50 nm on the entire surface, and a photoresist layer is formed thereon. This photoresist layer is then patterned to form a photoresist 81 that has an opening portion 82 having the same inner diameter as the above-mentioned through hole, and covers the area other than the upper part of this through hole. Further, the photoresist 81 is heat-treated at 200 to 300° C., and the photoresist 81 is allowed to reflow, and the inner diameter of the opening portion 82 is reduced, thereby forming a photoresist 83 having an opening portion 84, the inner diameter of which is the same as that of the read connecting plug 41. In FIG. 4C, the solid line represents the cross-sectional shape of the photoresist 81, and the dotted line represents the cross-sectional shape of the after-reflow photoresist 83. Alternatively, the method of reducing the opening portion of the photoresist may be, for example, the above-noted method employing sidewall formation.

Referring to FIG. 4D, by etching using, as mask, the photoresist 83 with the opening portion 54 whose diameter is diminished, the insulating layer 54, the write word line 14 and the interlayer insulating film (silicon oxide film) 52 are etched sequentially, thereby forming a connecting hole 25 that reaches a read landing pad 43. The photoresist 83 is then removed by ashing.

Referring to FIG. 4E, the connecting hole 25 is filled with a tungsten layer by CVD method, and the surface is then planarized by CMP, thereby forming a read connecting plug 41.

The second preferred embodiment does not include the step of forming a sidewall at an opening portion, and therefore offers the advantage that it is easy to apply to such an opening portion that has a small inner diameter and a large aspect ratio, thus involving the difficulty of forming a sidewall. The second preferred embodiment is otherwise substantially similar to the first preferred embodiment. Needless to say, the same operational effect as that of the first preferred embodiment can be expected.

Thus, with the MRAM structure and the manufacturing method thereof according to the second preferred embodiment, the conventional extraction wiring portion can be eliminated, and the length in the direction along a bit line can be reduced. It is therefore possible to realize, as the area of a memory cell, a cell size of not more than 8F², where F is the minimum dimension of wiring on the design rule. Furthermore, since the TMR element 10C requires only one-stage etching, the TMR element can be manufactured by etching with relatively low accuracy.

### Third Preferred Embodiment

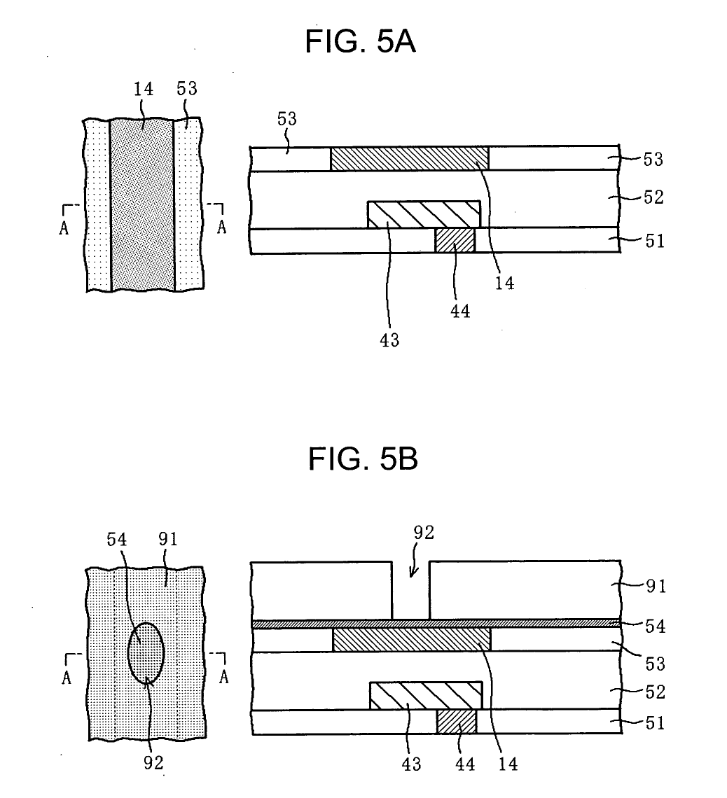

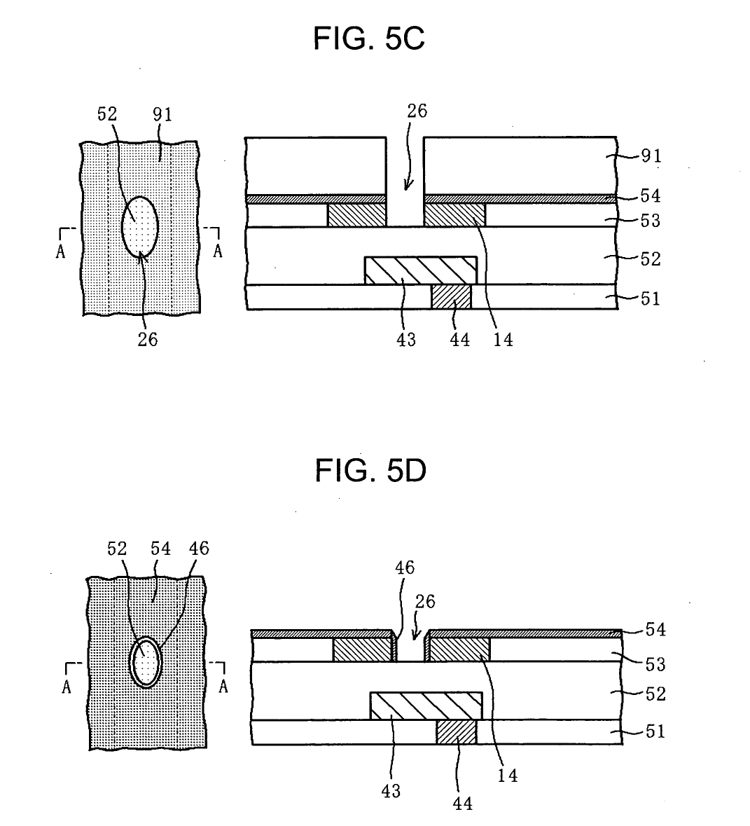

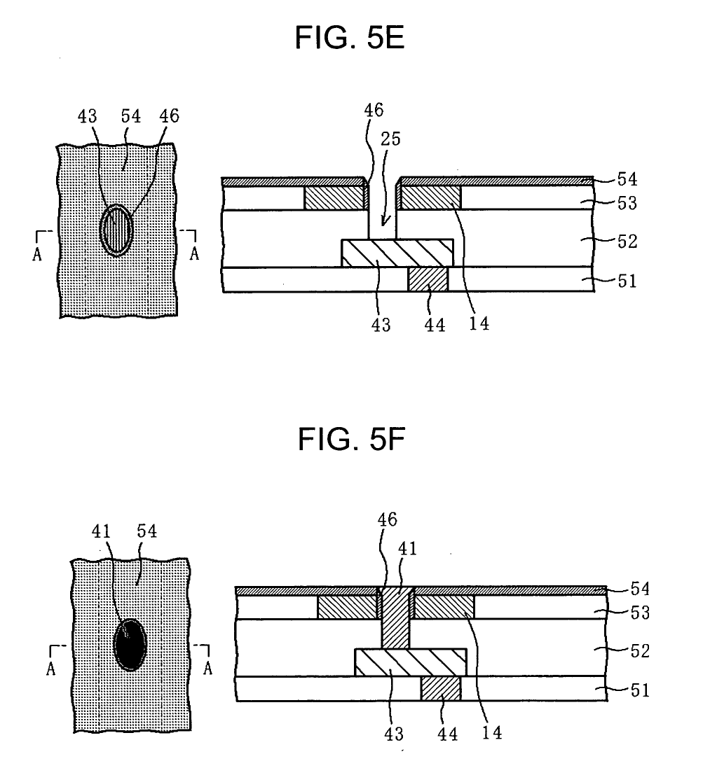

In FIGS. 5A to 5F, the left drawings are plan views showing the steps of manufacturing a MRAM, having substantially the same structure as the MRAM of the first preferred embodiment, by a method according to a third preferred embodiment, and the right drawings are sectional views taken along the line A-A in their respective plan views. These drawings represent from the same state as in FIG. 3B to the state corresponding to FIG. 3F. The descriptions of the succeeding steps are omitted because they are the same as in the first preferred embodiment.

In the third preferred embodiment, a connecting hole 25 that reaches a read land 43 is not formed at one time. For example, a connecting hole can be formed so as to reach a position at which it penetrates a write word line 14. In this state, an insulation sidewall is formed. With this sidewall as mask, a connecting hole is formed so as to reach the read land 43.

Referring to FIG. 5A, on an interlayer insulating film 52 composed of a silicon oxide film formed by high density plasma CVD method, titanium (20 nm), titanium nitride (20 nm), aluminum-copper alloy (300 nm), titanium (10 nm), and titanium nitride (100 nm) are deposited sequentially and then patterned by etching with photoresist as mask, thereby forming a write word line 14. Subsequently, a silicon oxide film is deposited in a thickness of 500 nm by high density plasma CVD method and then planarized by CMP, such that the surface of the write word line 14 is exposed, thereby forming an interlayer insulating film 53.

Referring to FIG. 5B, an insulating layer 54 composed of aluminum oxide (alumina) is deposited in a thickness of 50 nm on the entire surface, and a photoresist layer is formed thereon. This photoresist layer is then patterned to form a photoresist 91 having an opening portion 92. The opening portion 92 has the same inner diameter as the connecting hole 25.

Referring to FIG. 5C, by etching using, as mask, the photoresist 91, an insulating layer 54 and the write word line 14 are etched sequentially, thereby forming a connecting hole 26 that reaches the interlayer insulating film 52. The photoresist 91 is then removed by ashing.

Referring to FIG. 5D, a silicon nitride film is deposited in a thickness of 20 nm by plasma CVD method, and etch back is then performed to form in the connecting hole 26 an insulation sidewall 46 composed of the silicon nitrde film.

Referring to FIG. 5E, by using, as mask, the insulating layer 54 and the sidewall 46 composed of the silicon nitride film, the interlayer insulating film 52 is etched to form a connecting hole 25 that reaches the read landing pad 43.

Referring to FIG. 5F, the connecting hole 25 is filled with a tungsten layer by CVD method, and the surface is then planarized by CMP, thereby forming the read connecting plug 41.

With the third preferred embodiment, though it contains the step of forming the sidewall at the opening portion, the depth of the opening portion is less than one half of that in the first preferred embodiment, thereby facilitating the step of forming the sidewall. In addition, the third preferred embodiment offers the advantage of including only one mask-forming step, in contrast with two for the second preferred embodiment. The third preferred embodiment is otherwise substantially similar to the first preferred embodiment. Needless to say, the same operational effect as that of the first preferred embodiment can be expected.

Thus, with the MRAM structure and the manufacturing method thereof according to the third preferred embodiment, the conventional extraction wiring portion can be eliminated, and the length in the direction along a bit line can be reduced. It is therefore possible to realize, as the area of a memory cell, a cell size of not more than 8F², where F is the minimum dimension of wiring on the design rule. Furthermore, since the TMR element 10C requires only one-stage etching, the TMR element can be manufactured by etching with relatively low accuracy.

### Fourth Preferred Embodiment

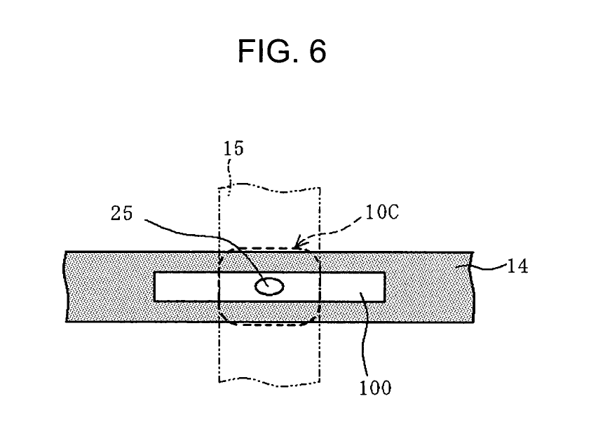

FIG. 6 is a plan view schematically showing an important part of a MRAM according to a fourth preferred embodiment. A write word line 14 of FIG. 6 has a notch portion 100 in the shape of a rectangle. The write word line 14 is divided into two sides by the notch portion 100. A connecting hole 25 is disposed between the two sides. A read connecting plug 41 is formed within the connecting hole 25.

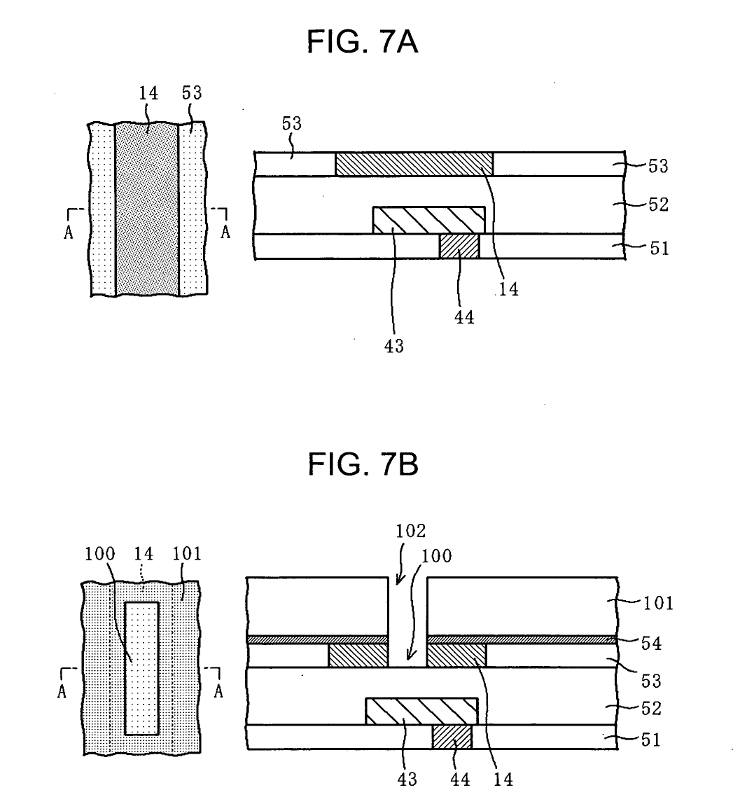

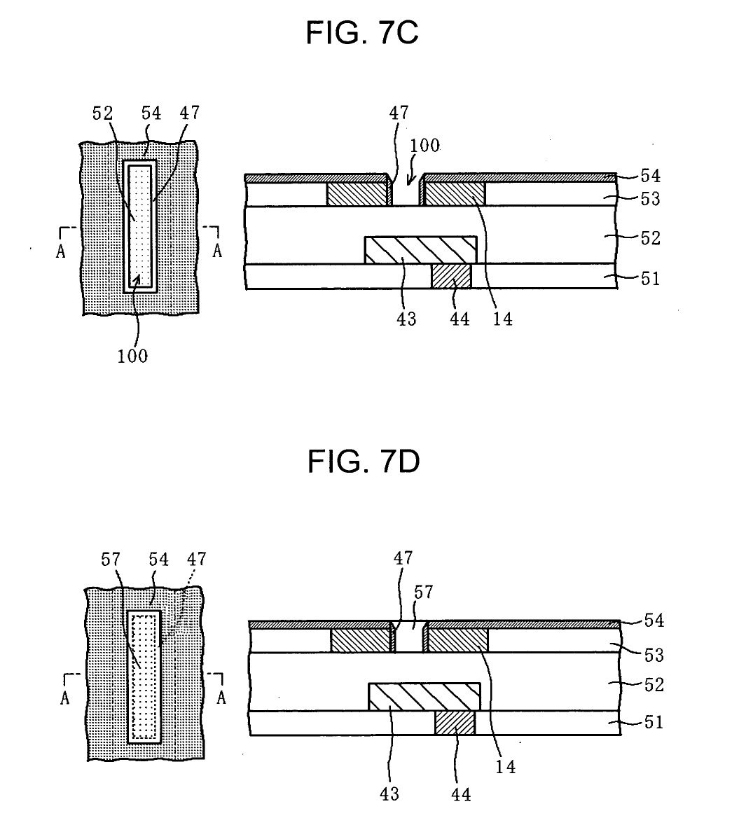

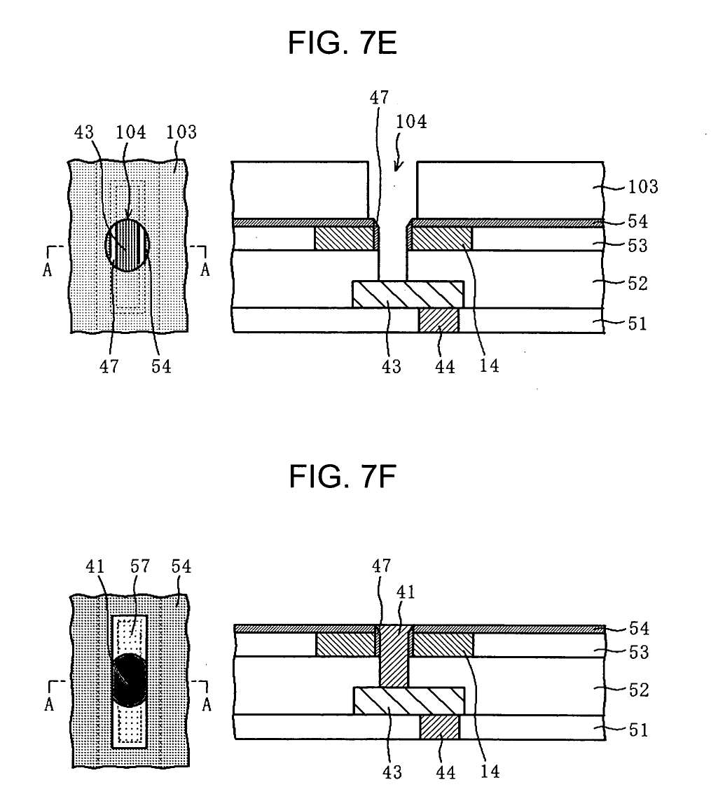

In FIGS. 7A to 7F, the left drawings are plan views showing the steps of manufacturing a MRAM, having substantially the same structure as the MRAM of the first preferred embodiment, by a method according to a fourth preferred embodiment, and the right drawings are sectional views taken along the line A-A in their respective plan views. These drawings represent from the same state as in FIG. 3B to the state corresponding to FIG. 3F.

Referring to FIG. 7A, on an interlayer insulating film 52 composed of a silicon oxide film formed by high density plasma CVD method, titanium (20 nm), titanium nitride (20 nm), aluminum-copper alloy (300 nm), titanium (10 mm), and titanium nitride (100 nm) are deposited sequentially and then patterned by etching with a photoresist as mask, thereby forming a write word line 14. Subsequently, a silicon oxide film is deposited in a thickness of 500 nm by high density plasma CVD method, and then planarized by CMP, such that the surface of the write word line 14 is exposed, thereby forming an interlayer insulating film 53.

Referring to FIG. 7B, an insulating layer 54 composed of aluminum oxide (alumina) is deposited in a thickness of 50 nm on the entire surface, and a photoresist layer is formed thereon. This photoresist layer is then patterned to form a photoresist 101 having a rectangular opening portion 102. With the photoresist 101 as mask, the insulating layer 54 and the write word line 14 are etched sequentially, thereby forming the write word line 14 having the rectangular notch portion 100. The photoresist 101 is then removed by ashing.

Referring to FIG. 7C, a silicon nitride film is deposited in a thickness of 20 nm by plasma CVD method, and etch back is then performed to form in the notch portion 100 an insulation sidewall 47 composed of the silicon nitrdie film.

Referring to FIG. 7D, the rectangular notch portion 100 is filled with a silicon oxide film by high density plasma CVD method, and the surface is then planarized by CMP, such that the surface of the write word line 14 is exposed, thereby forming an insulating layer 57.

Referring to FIG. 7E, a photoresist layer is formed and patterned to form a photoresist 103 having an opening portion 104 that is, for example, in the shape of an ellipse. With the photoresist 103 as mask, the insulating layer 57 and the interlayer insulating film 52 are etched sequentially to form a connecting hole 106 (not shown) having a cross-section in the shape of a partially notched ellipse. The photoresist 103 is then removed by ashing.

Referring to FIG. 7F, a tungsten film is deposited by CVD method, and the surface is then planarized by CMP, thereby forming a read connecting plug 41.

In accordance with the fourth preferred embodiment, after the insulation sidewall 47 is formed on the write word line 14, with this sidewall as mask, the connecting hole 106 that reaches the read land 43 is formed. This provides the advantage that the connecting hole 106 is accomplished by etching with relatively low accuracy. Although this process includes the step of forming the sidewall at the opening portion, the opening portion is of a wide rectangle, thus facilitating the formation of the sidewall. In addition, since the connecting hole 106 is formed after forming the large opening portion, the aspect ratio of the connecting hole 106 becomes small, which facilitates the formation.

Meanwhile, there is a fear that the presence of the notch portion 100 on the write word line 14 reduces the cross-sectional area at the region of the write word line 14 at which the notch portion 100 is formed, and this region has a shorter lifetime with respect to electro migration than other regions. However, with the fourth preferred embodiment, for example, the danger that the write word line 14 causes fusing due to electro migration is minimized by limiting the region for disposing the notch portion 100 to part of the write word line 14.

The fourth preferred embodiment is otherwise substantially similar to the first preferred embodiment. Needless to say, the same operational effect as that of the first preferred embodiment can be expected. Specifically, with the MRAM structure and the manufacturing method thereof according to the fourth preferred embodiment, the conventional extraction wiring portion can be eliminated, and the length in the direction along a bit line can be reduced. It is therefore possible to realize, as the area of a memory cell, a cell size of not more than 8F₂, where F is the minimum dimension of wiring on the design rule. Furthermore, since the TMR element 10C requires only one-stage etching, the TMR element can be manufactured by etching with relatively low accuracy.

### Fifth Preferred Embodiment

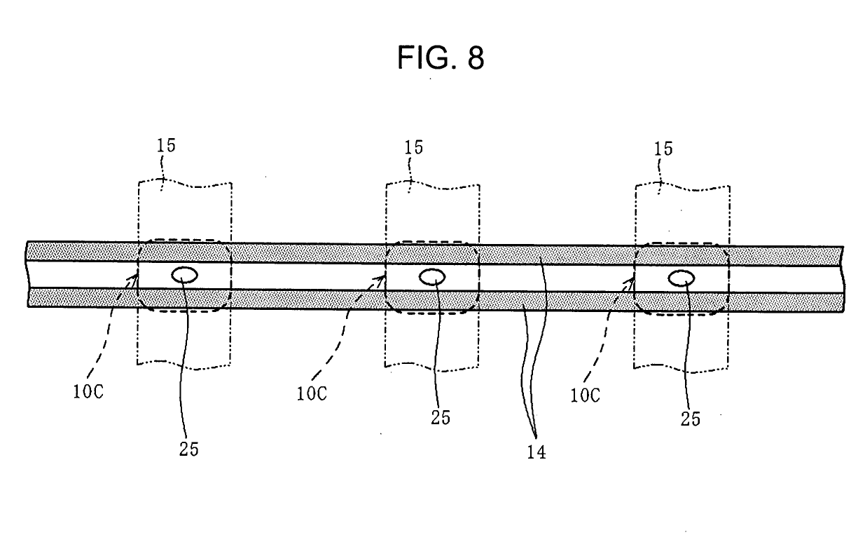

FIG. 8 is a plan view schematically showing an important part of a MRAM according to a fifth preferred embodiment. In this embodiment, a write word line 14 comprises two or more wirings. A connecting hole 25 is disposed between the wirings, and a read connecting plug 41 is formed within the connecting hole 25. This shape is similar to that of the write word line in the fourth preferred embodiment, and it can be regarded as the shape in which the notch portion 100 of the fourth preferred embodiment is enlarged in the direction along a bit line, resulting in a connection between memory cells.

The write word line 14 is connected, at its end portion, to an underlayer wiring of a peripheral circuit section. A plurality of wirings constituting the write word line 14 are preferably electrically connected to each other on this underlayer wiring. Alternatively, they may be connected to each other at the position of an end portion before they reach the underlayer wiring.

For example, the plurality of wirings constituting the write word line 14 is obtainable by forming a plurality of wirings with a minimum pitch when forming the wirings. Alternatively, like the fourth preferred embodiment, a single wiring is first formed and then divided into a plurality of ones. At this time, however, the division should be performed throughout the entire wiring length.

After forming the plurality of wirings, a connecting hole 25 and a read connecting plug 41 are formed between the wirings. Since these steps are the same as that described with reference to FIGS. 7A to 7F in the fourth preferred embodiment, they are omitted herein to avoid overlapping.

The fifth preferred embodiment is otherwise substantially similar to the first and the fourth preferred embodiments. Needless to say, the same operational effect as that of the first preferred embodiment can be expected. Specifically, with the MRAM structure and the manufacturing method thereof according to the fifth preferred embodiment, the conventional extraction wiring portion can be eliminated, and the length in the direction along a bit line can be reduced. It is therefore possible to realize, as the area of a memory cell, a cell size of not more than 8F₂, where F is the minimum dimension of wiring on the design rule. Furthermore, since the TMR element 10C requires only one-stage etching, the TMR element can be manufactured by etching with relatively low accuracy.

The foregoing description illustrates and describes the present invention based on the preferred embodiments. However, it is to be understood that the invention is capable of using in various other modifications within the scope of the inventive concept.

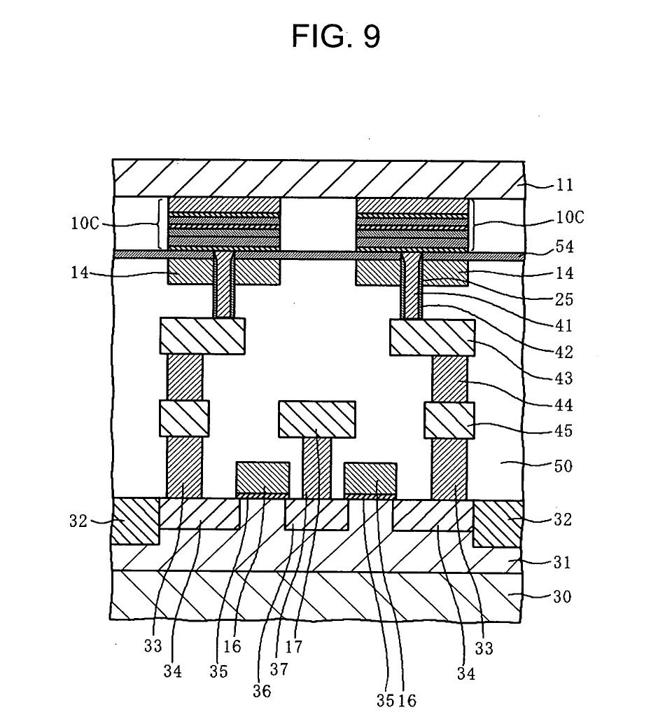

For instance, the first preferred embodiment illustrates the case where the write bit line 13 and the read bit line 15 are disposed individually, but the two lines may share one bit line 11, as shown in FIG. 9.

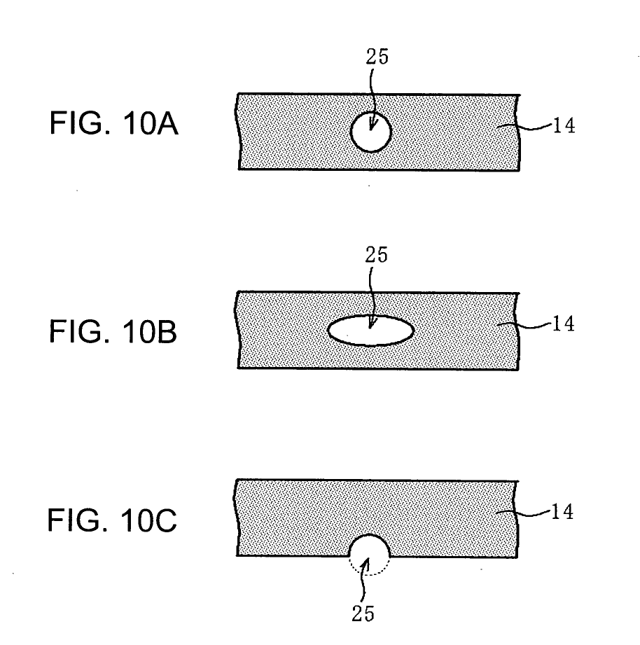

Additionally, the shape of the connecting hole 25 to be formed at the write word line 14 may be a circle or an ellipse as shown in FIGS. 10A and 10B, respectively. Alternatively, part of these may penetrate the write word line 14.

It is estimated that MRAMs are essential in the era of Ubiquitous, as high speed and non-volatile large scale memory. They are suitable for all electric apparatuses, in particular, information communication equipment demanding further higher performance such as higher speed, lower power consumption and higher integration. This is especially so for personal small equipment such as portable terminals.

1. A magnetic memory device in which:
a tunnel magnetic resistance effect element is configured by stacking a fixed magnetic layer whose direction of magnetization is fixed, a tunnel barrier layer, and a free magnetic layer whose direction of magnetization is variable in this order; and
a second wiring is arranged opposite to the tunnel magnetic resistance effect element via an insulating layer on the side opposite a first wiring electrically connected to the tunnel magnetic resistance effect element, wherein
a third wiring for reading electrically connected to the tunnel magnetic resistance effect element on the same side as the second wiring with respect to the tunnel magnetic resistance effect element is disposed within a connecting hole which is formed in an electrically isolated state with the second wiring while penetrating at least part of an area of the second wiring.

2. The magnetic memory device as cited in claim 1, wherein
an insulating layer is formed on the sidewall of the connecting hole; and
the third wiring is buried at the inside of the insulating layer.

3. The magnetic memory device as cited in claim 1, wherein
the connecting hole penetrates the area of the second wiring.

4. The magnetic memory device as cited in claim 1, wherein
the second wiring is divided at least by the magnetic memory element, into both sides of the connecting hole.

5. The magnetic memory device as cited in claim 1, wherein
there is disposed a fourth wiring for writing that is electrically isolated from the tunnel magnetic resistance effect element on the same side as the first wiring with respect to the tunnel magnetic resistance effect element.

6. The magnetic memory device as cited in claim 1, wherein
the first wiring acts as the wiring for reading and the wiring for writing.

7. The magnetic memory device as cited in claim 1, wherein
the first wiring and the second wiring are arranged to cross each other; and
the tunnel magnetic resistance effect element is arranged at the cross-point.

8. The magnetic memory device as cited in claim 1, wherein
the tunnel barrier layer is interposed between the fixed magnetic layer and the free magnetic layer, so that information is written by magnetizing the free magnetic layer in a predetermined direction with a magnetic field induced by passing current to the first or fourth wiring and the second wiring; and
the written information is read through the third wiring by tunnel magnetic resistance effect via the tunnel barrier layer.

9. A manufacturing method of a magnetic memory device in which:
a tunnel magnetic resistance effect element is configured by stacking a fixed magnetic layer whose direction of magnetization is fixed, a tunnel barrier layer, and a free magnetic layer whose direction of magnetization is variable in this order;
a second wiring is arranged opposite to the tunnel magnetic resistance effect element via an insulating layer on the side opposite a first wiring electrically connected to the tunnel magnetic resistance effect element; and
a third wiring for reading electrically connected to the tunnel magnetic resistance effect element on the same side as the second wiring with respect to the tunnel magnetic resistance effect element is disposed within a connecting hole which is formed in an electrically isolated state with the second wiring while penetrating at least part of an area of the second wiring, comprising:
a step of forming the second wiring;
a step of forming the connecting hole which penetrate at least the part of the area of the second wiring; and
a step of forming the third wiring within the connecting hole in an electrically isolated state with the second wiring.

10. The manufacturing method of the magnetic memory device as cited in claim 9, wherein
an insulating layer is formed on the sidewall of the connecting hole; and
the third wiring is buried at the inside of the insulating layer.

11. The manufacturing method of the magnetic memory device as cited in claim 9, wherein
the connecting hole penetrates the area of the second wiring.

12. The manufacturing method of the magnetic memory device as cited in claim 9, wherein
the second wiring is divided at least by the magnetic memory element, into both sides of the connecting hole.

13. The manufacturing method of the magnetic memory device as cited in claim 9, wherein
there is disposed a fourth wiring for writing that is electrically isolated from the tunnel magnetic resistance effect element on the same side as the first wiring with respect to the tunnel magnetic resistance effect element.

14. The manufacturing method of the magnetic memory device as cited in claim 9, wherein
the first wiring acts as the wiring for reading and the wiring for writing.

15. The manufacturing method of the magnetic memory device as cited in claim 9, wherein
the first wiring and the second wiring are arranged to cross each other; and
the tunnel magnetic resistance effect element is arranged at the cross-point.

16. The manufacturing method of the magnetic memory device as cited in claim 9, wherein
the tunnel barrier layer is interposed between the fixed magnetic layer and the free magnetic layer, so that information is written by magnetizing the free magnetic layer in a predetermined direction with a magnetic field induced by passing current to the first or fourth wiring and the second wiring; and
the written information is read through the third wiring by tunnel magnetic resistance effect via the tunnel barrier layer.
